(19) United States
(12) Patent Application Publication
(10) Pub. No.: US 2007/0123068 A1
(43) Pub. Date: May 31, 2007

(54) Conductive ball arraying apparatus

(75) Inventor: Kazuo Niizuma, Ishikawa (JP)

Correspondence Address: DRINKER BIDDLE & REATH (DC), 1500 K STREET, N.W., SUITE 1100, WASHINGTON, DC, 20005-1209, US

(73) Assignee: SHIBUYA KOGYO CO., LTD.

(21) Appl. No.: 11/605,396

(22) Filed: Nov. 29, 2006

(30) Foreign Application Priority Data
Nov. 30, 2005 (JP) P2005-346414

(51) Int. Cl. H05K 1/00

(52) U.S. Cl. 439/70

(57) ABSTRACT

A conductive ball arraying apparatus adopts the following means. At first, the apparatus comprises an arraying jig having a conductive ball insert section formed in a predetermined area, a ball cup having an opening in its lower face and capable of housing a multiplicity of conductive balls together with the arraying jig, and moving means for moving the ball cup along the upper face of the arraying jig. Secondly, the conductive ball arraying apparatus moves the ball cup housing the conductive balls, along the upper face of the arraying jig so that the conductive balls may fall into the insert section of the arraying jig and may be arrayed. Thirdly, the moving means moves the ball cup zigzag.

This application claims priority from Japanese Patent Application No. 2005-346414, filed on Nov. 30, 2005, the entire subject matter of which is incorporated herein by reference.

### BACKGROUND OF THE INVENTION

1. Field of the Invention

The present invention relates to an improvement in an apparatus for arraying conductive balls on an arraying jig such that ball cups housing the conductive balls over the arraying jig and, more particularly, to a conductive ball arraying apparatus developed by noting the movements of the ball cups.

2. Description of the Related Art

In the related art, there is a solder ball mounting apparatus for mounting the solder balls on the individual electrodes formed in a predetermined array pattern on a mounting object, after an adhesive material was applied to the electrodes. As disclosed in JP-A-2001-35845, the solder balls are mounted on the individual electrodes of the mounting object after they are sucked and arrayed on the ball mounting head having the array plate. As the product of the mounting object such as a wafer becomes larger, the number of solder balls to be mounted at one time exceeds one million, and it is the current practice to reduce the defects at the time of arraying and mounting the solder balls.

As disclosed in Japanese Patent No. 3,271,482, therefore, there is provided an apparatus, in which an array mask (e.g., a template in Japanese Patent No. 3,271,482) is disposed above an electronic substrate such as the mounting object having printed flux. A ball cup (e.g., a solder ball housing section) moves over the array mask and drops the solder balls directly on the electrodes of an electronic substrate. However, the conductive ball arraying apparatus of this kind is encountered by many deformations of the conductive balls and many occurrences of foreign substances.

In the conductive ball arraying apparatus of this kind, as shown in FIG. 8A, solder balls 21 are pushed by a ball cup 23a to fall into an insert section 18. If the solder balls 21 are pushed straight, the solder ball 21A to be dropped is pushed straight, as shown in FIG. 8B, by solder balls 21B and 21C following the solder ball 21A, and is frequently clamped by the edge 18A of the insert section 18 of a ball array mask 19. By this clamping force, the solder ball 21A becomes chipped to form fragments, or the folder ball 21A is deformed by itself.

In the solder ball mounting apparatus disclosed in Japanese Patent No. 3,271,482, therefore, there has been developed means for moving a ball cup (e.g., a solder ball housing section) helically and horizontally. However, this helical movement is followed by the movement backward of the proceeding direction. This raises problems that it takes time to mount the balls, that a straight portion is formed in the movement in the proceeding direction thereby to cause the chipping of the balls, and that the transverse movement is uselessly invited by the helical movement to lower the efficiency.

### SUMMARY OF THE INVENTION

The invention has an object to move ball cups zigzag so that motions oblique to the proceeding direction may be given to conductive balls, as shown in FIG. 8C, thereby to facilitate the drops of the conductive balls while rolling into an insert section, and to make the conductive balls loose in ball cups by the zigzag motions of the ball cups so that the falling conductive balls may be clamped by the edge of the insert section of a ball array mask thereby to avoid the danger that the solder ball becomes chipped to form the foreign substance, or that the folder ball is deformed by itself.

In order to solve the problems, according to a first aspect of the invention, a conductive ball arraying apparatus comprising: an arraying jig having a conductive ball insert section; a ball cup having an opening in a lower face thereof and being capable of housing a plurality of conductive balls together with the arraying jig; and moving means which moves the ball cup zigzag along an upper face of the arraying jig and arrays the conductive balls.

According to a second aspect of the invention, the moving means moves the ball cup housing the conductive balls zigzag along the upper face of the arraying jig, falls the conductive balls from the opening of the ball cup into an insert section of the arraying jig and arrays the conductive balls.

According to a third aspect of the invention, the opening of the ball cup is narrower than the width of the area, and when the proceeding direction of the ball cup is turned, the moving means moves perpendicularly to the proceeding direction.

According to a fourth aspect of the invention, a zigzag width of the direction to intersect the proceeding direction of the ball cup is one half or less of the array pitch in the same direction as that of an insert section of the arraying jig. According to a fifth aspect of the invention a quantity of the conductive balls to be housed in the ball cup is kept within a predetermined range.

According to the first and second aspects of the invention, the moving means moves the ball cups zigzag. Therefore, motions oblique to the proceeding direction can be given to conductive balls thereby to facilitate the drops of the conductive balls while rolling into an insert section, and to make the conductive balls loose in ball cups by the zigzag motions of the ball cups so that the falling conductive balls can be clamped by the edge of the insert section of a ball array mask. Accordingly, the danger that the solder ball becomes chipped to form the fragments, or that the folder ball is deformed by itself can be avoided.

According to the third aspect of the invention, even if the opening for the ball cup is narrower than the width of the area, the moving means moves, when the proceeding direction of the ball cup is turned, perpendicularly of the proceeding direction. As a result, the solder balls can be efficiently arrayed all over the wafer.

According to the fourth aspect of the invention, the zigzag width of the direction to intersect the proceeding direction of the ball cup is one half or less of the array pitch in the same direction as that of an insert section of the arraying jig. As a result, the ball cup can be prevented from doubly moving to the insert section having the conductive balls inserted. Accordingly, the useless motions can be eliminated.

According to the fifth aspect of the invention, the quantity of the conductive balls to be housed in the ball cup is kept within a predetermined range. As a result, it is possible to eliminate the troubles that the conductive balls in the ball cup are too many to move in the lowermost layer while pushing one another and to fall into the insert section, and that the conductive balls in the ball cup are so few that they come out, thereby to improve the productivity of the conductive ball arraying apparatus.

### BRIEF DESCRIPTION OF THE DRAWINGS

FIG. 1 is a schematic top plan view showing the entirety of a solder ball mounting apparatus according to the embodiment;

FIG. 2 is a schematic top plan view showing the case, in which a wafer supply section and a wafer housing section are disposed in the same direction;

FIG. 3 is an explanatory view showing the movements of a wafer transfer stage;

FIG. 4 is a partially sectional side elevation of a ball mounting section;

FIG. 5 is a top plan view of the ball mounting section;

FIG. 6 is an explanatory view showing the movement of a ball cup;

FIG. 7 is an explanatory view of the zigzag width in a direction to intersect the proceeding direction of the ball cup; and

FIGS. 8A to 8C are explanatory views showing relations between solder balls and an insert section: (A) an explanatory section; (B) an explanatory top plan view of the case, in which the solder balls are pushed straight; and (C) an explanatory top plan view of the case, in which the solder balls are pushed obliquely.

### DETAILED DESCRIPTION OF THE PREFERRED EMBODIMENTS

The invention is described in the following in connection with its embodiment with reference to the accompanying drawings. In the invention, an object, on which conductive balls are to be mounted, is exemplified by a semiconductor wafer (as will be merely called as the “wafer”), an electronic circuit substrate or a ceramic substrate, but the embodiment uses a wafer 14. On the other hand, an adhesive material is exemplified by flux, solder paste or a conductive adhesive, but the embodiment uses the flux.

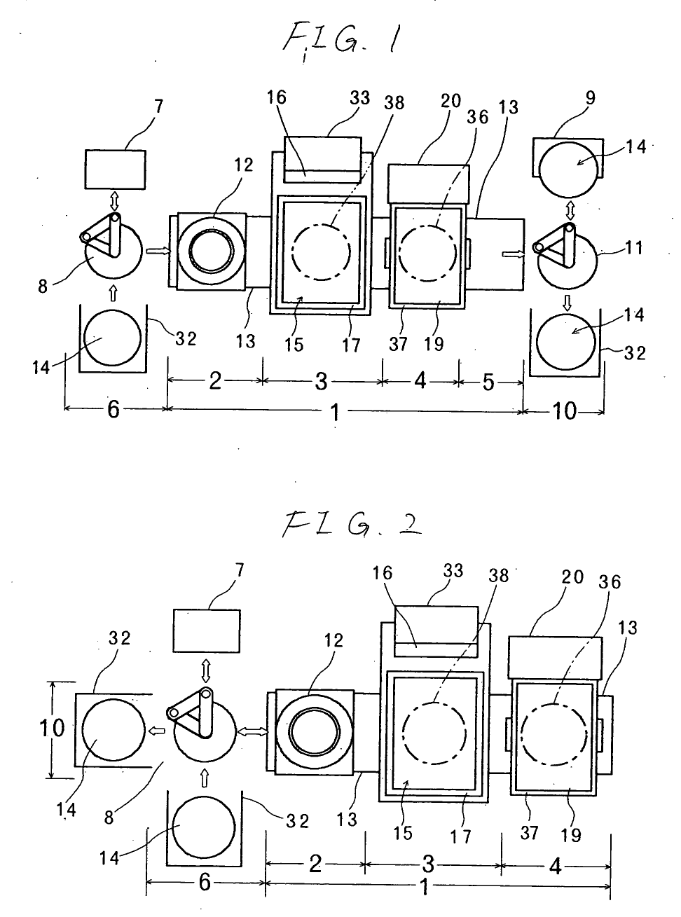

FIG. 1 is a schematic top plan view showing the entirety of a solder ball mounting apparatus 1. The solder ball mounting apparatus 1 includes a carry-in wafer transfer section 2, a flux printing section 3, a ball mounting section 4 and a carry-out wafer transfer section 5, as recited in the order from the left-hand side of FIG. 1. A wafer supply section 6, a primary alignment section 7 and a carry-in robot 8 exist at the pretreatment of the solder ball mounting apparatus 1. An inverting unit 9, a wafer housing section 10 and a carry-out robot 11 exist at the post-treatment.

The primary alignment section 7 of the pretreatment rotates the wafer 14 in a horizontal plane so that it detects the position of the orientation flat or notch of the wafer 1 thereby to correct the rough position of the wafer 14 and to set the wafer 14 in the wafer transfer section in a predetermined direction. On the other hand, the inverting unit 9 of the post-treatment rotates the wafer 14 in the horizontal direction so that it rotates the orientation flat and the notch of the wafer 14 to a predetermined position thereby to house them in a cassette 32.

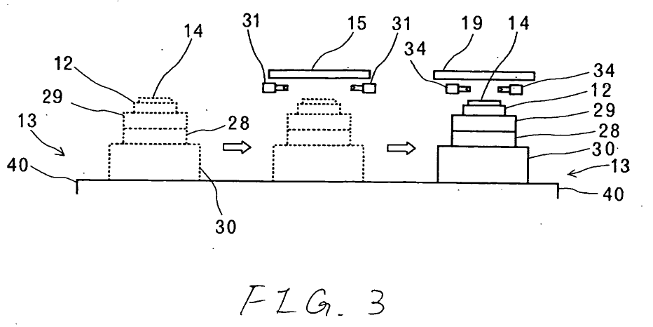

A wafer transfer stage 12 and a transfer passage 13 which transfers the wafer 14 from the wafer transfer section 2 to the flux printing section 3, the ball mounting section 4 and the wafer transfer section 5 are formed in the solder ball mounting apparatus 1. The transfer passage 13 is equipped, as shown in FIG. 3, with an X-axis (rightward and leftward, as shown) moving device 40 of the transfer stage 12, as shown in FIG. 3.

The flux printing section 3 has a flux supply device 16, a printing mask 15 for printing a flux or an adhesive material on the wafer 14, and vertical observation cameras 31 for observing the alignment marks of the wafer 14 and the printing mask 15 thereby to position the wafer 14 and the printing mask, as shown in FIG. 3. The printing mask 15 has a through hole formed and arrayed to the pattern of the electrodes on the wafer 14. Alignment marks (although not shown) are displayed at two portions on the lower face of the printing mask 15 in a through hole forming area 38 and are adhered to a mold 17 and held in a stationary portion such as the frame.

The flux supply device 16 moves the squeegee (although not shown) along the upper face of the printing mask 15 so that the flux is printed in the through holes of the printing mask 15 and fed to the electrodes of the wafer 14. Here, numeral 33 designates a cleaning unit for removing the flux from the printing mask 15.

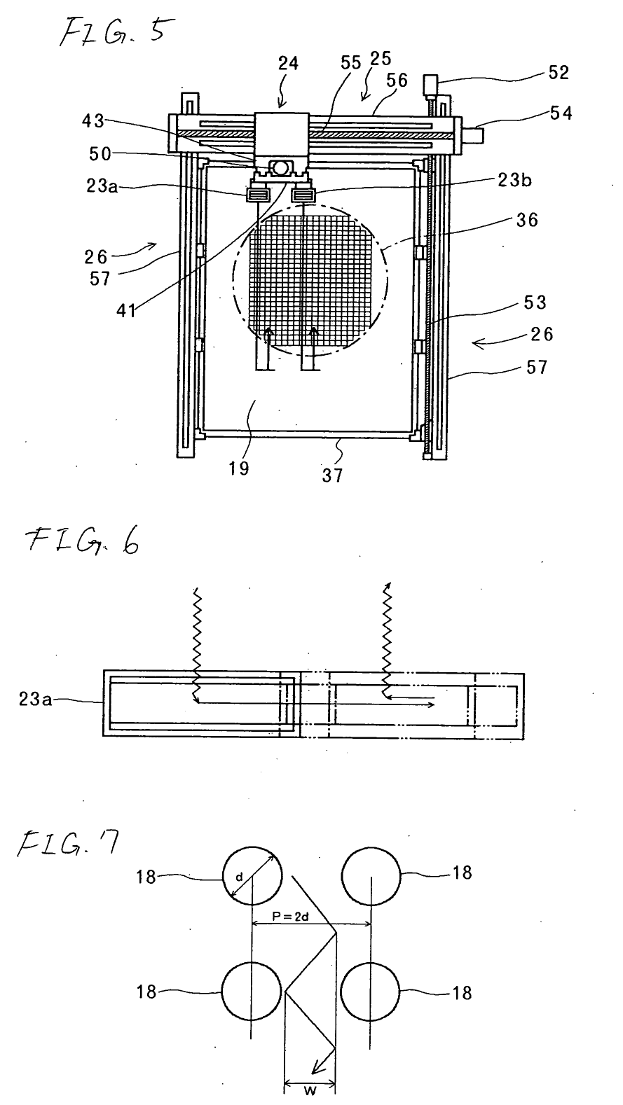

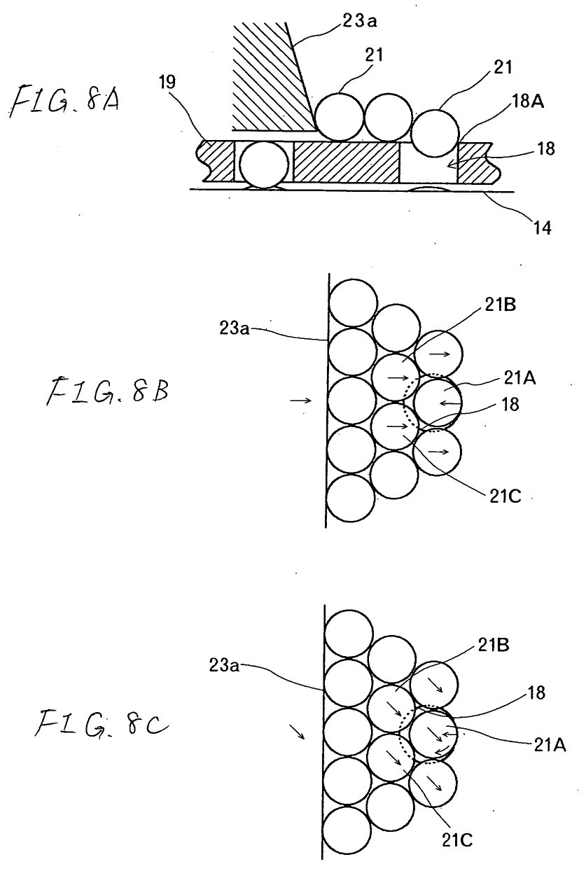

The ball mounting section 4 has a solder ball supply device 20, an insert section 18 (as shown in FIG. 4 and FIG. 7) arrayed to the pattern of the electrodes on the wafer 14, a ball array mask 19 as a plurality of arraying jigs, and vertical observation cameras 34 (as shown in FIG. 3) for observing and positioning the wafer 14 and the alignment marks of the ball array mask 19.

The thickness of the ball array mask 19 is substantially equal to the diameter of solder balls 21, and the diameter of the insert section 18 is made slightly larger than that of the solder balls. The transverse array pitch P of the insert section 18 of the ball array mask 19 is generally about twice as large as the hole diameter d of the insert section 18, as shown in FIG. 7. As in the printing mask 15, two alignment marks (not-shown) are formed on the lower face in an insert section forming area 36 in the ball array mask 19. The ball array mask 19 is adhered to a mold 37 and is fixed on the stationary portion such as the frame.

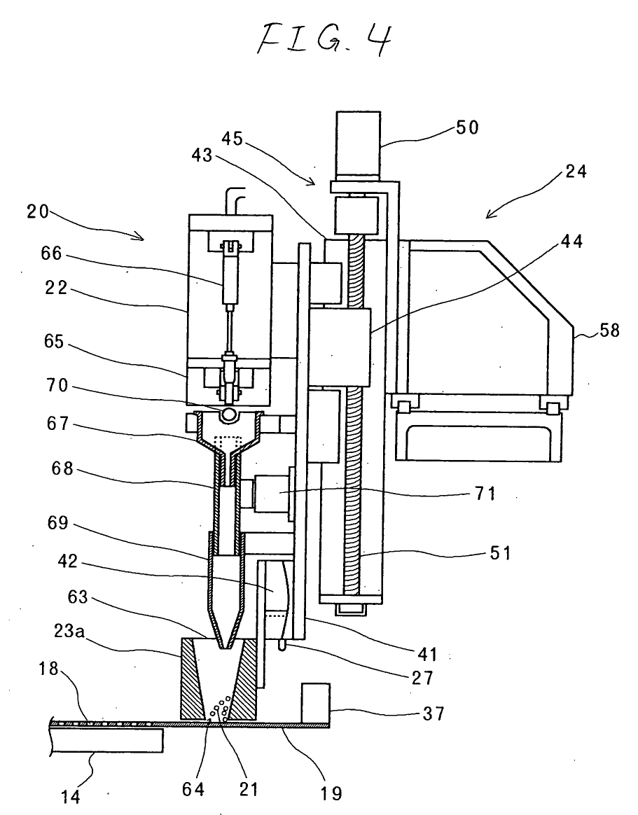

As shown in FIG. 4, the solder ball supply device 20 has a ball hopper 22 for reserving a number of solder balls 21, ball cups 23a and 23b for dropping the solder balls 21 onto the ball array mask 19, ball cup moving means 24 for moving the ball cups 23a and 23b in the X-axis direction and in Y-axis direction as shown in FIG. 5, and lifting means 45 for moving the ball cups 23a and 23b in the Z-axis direction.

The ball cups 23a and 23b are formed to have rectangular openings 63 in the upper portions for supplying the balls, and rectangular openings 64 in the lower face for dropping the balls. The ball cups 23a and 23b have their inner walls formed to converge toward the openings 64.

The ball cup moving means 24 acting as the means for moving these ball cups 23a and 23b in the horizontal plane has an X-axis drive mechanism 25 and a Y-axis drive mechanism 26 as shown in FIG. 5. The X-axis drive mechanism 25 moves a base member 58, in which the ball cups 23a and 23b are provided, through the lifting means 45 along an X-axis guide 56 in the X-axis direction by a threaded bar 55 rotated by an X-axis drive motor 54. The Y-axis drive mechanism 26 moves the base member 58 together with the X-axis drive mechanism 25, along a Y-axis guide 57 in the X-axis direction by a threaded bar 53 rotating the base member 58 together with the X-axis drive mechanism 25 by a Y-axis drive motor 52. Specifically, the ball cups 23a and 23b are moved zigzag in the Y-axis direction as indicated by arrows in FIGS. 5 and 6, by associating the Y-axis drive mechanism 26 and the X-axis drive mechanism 25. The movements are returned in the Y-axis direction to repeat the actions to move zigzag in the Y-axis direction, so that the solder balls 21 are dropped and fitted in the insert section 18 of the ball array mask 19. By thus moving the ball cups 23a and 23b zigzag, the ball cups 23a and 23b are always move obliquely forward with respect to the inner wall faces of the ball cups 23a and 23b to push the solder balls 21, so that the solder balls 21 become easy to fall down into the insert section 18. Here, the width W, as taken in the direction to intersect the forward direction of the ball cups 23a and 23b in the zigzag movement is one half of or less than the array pitch P of the insert section 18, as taken in the same direction in FIG. 7.

The ball cups 23a and 23b are provided in parallel with each other in a transverse direction (in a direction of the X-axis) as shown in FIG. 5. The ball cups 23a and 23b are attached to the common mounting base 41 thereby to cover the whole mounting area. Thus, the productivity is improved by covering the whole area of the wafer 14 with the two ball cups 23a and 23b. Here, these ball cups 23a and 23b may be made wider than the insert section forming area 36. In this case, the X-axis drive mechanism 25 need not be provided but may be reciprocated in the Y-axis direction.

In the lifting means 45 for the ball cups 23a and 23b, the mounting base 41 is mounted through a nut member 44 on a threaded bar 51 which is rotated by an Z-axis drive motor 50 belonging to the base member 58 of the ball cup moving means 24, as shown in FIG. 4, so that the mounting base 41 can moved upward and downward along a guide rail 43. The ball cup 23a is attached to the mounting base 41 through an inclination adjusting mechanism 42 for adjusting the mounting inclination of the ball cup 23a. Here, the ball cups 23a and 23b are inclined when they are assembled.

The ball hopper is provided above the ball supply openings 63 of the ball cups 23a and 23b. The ball hopper 22 reserves a number of solder balls 21 in its internal space. The ball hopper 22 has a supply port for discharging the reserved solder balls 21 to the ball cups 23a and 23b, and a shutter 65 acting as open/close means for opening/closing the supply port. The ball hopper 22 is attached to the mounting base 41 shared by the ball cups 23a and 23b. Numeral 66 designates a cylinder for actuating the shutter 65. Here, the ball hopper 22 is replaced by another according to the sizes and materials of the solder balls 21.

A receiving portion 67 having a ball detecting mechanism, a switching portion 68 for switching the supply of the balls to the left and right ball cups 23a and 23b, and a ball introduction portion 69 for introducing the solder balls 21 into the ball cups 23a and 23b are provided below the ball supply port of the ball hopper 22. A ball detection sensor 70, which is provided in the receiving portion 67, detects the supply and the clogging of the solder balls 21 supplied from the ball supply port of the ball hopper 22 and is exemplified in the embodiment by a flooding/receiving type sensor. The switching portion 68 is rocked by a rocking type air cylinder 71 thereby to share the solder balls 21 from the receiving portion 67 to the left and right ball cups 23a and 23b through the ball introduction portions 69.

The ball supplying action comes in when the shutter 65 of the ball hopper 22 is opened. The ball supply timing for the action of the shutter 65 is determined in advance from the solder ball array number. The ball supply is predetermined for the ball supply time when the shutter 65 is opened. Here, the contents of the solder balls 21 in the ball cups 23a and 23b are grasped from the ball supply from the ball hopper 22 and the ball discharge from and according to the ball cups 23a and 23b, and the optimum contents of the solder balls in the ball cups 23a and 23b are determined in advance.

The ball supplying action is performed in the following manners. At first, the vacuum in the ball hopper 22 is turned ON. Then, the shutter 65 is opened. Next, the vacuum in the ball hopper 22 is turned OFF so that the solder balls 21 in the ball hopper 22 fall from the supply port into the receiving portion 67. At this time, the solder balls 21 having fallen into the receiving portion 67 are detected by the ball detection sensor 70. After lapse of a predetermined time period, the vacuum in the ball hopper 22 is turned ON to stop the drop of solder balls 21, and the shutter 65 is closed to turn OFF the vacuum.

The solder balls 21 having fallen into the receiving portion 67 are supplied through the switching portion 68 and the ball introduction portion 69 into one ball cup 23a. When the supply to one is completed, the ball cups 23a and 23b to be supplied are switched. Then, the rocking type air cylinder 71 is activated to switch the introduction direction of the switching portion 68 thereby to complete the preparation for the ball supply to the other ball cup 23b.

Here, the ball supplying action is repeated again to supply the balls to the other ball cup 23b. The actions thus far described are repeated to perform the ball supply finely. This ball supplying action may be performed by stopping the ball cups 23a and 23b but can also be performed while moving the same.

The mask height detection sensor 27 is attached to the vicinity of the ball cups 23a and 23b and may be either of contact type or of noncontact type. The mask height detection sensor 27 is exemplified by a laser sensor or an electrostatic capacitive sensor. The mask height detection is performed at the time when the ball array mask 19 is changed at the initial setting time or at the mold changing type and after the mold 37 of the ball array mask 19 is fixed at the support portion on the frame side. Specifically, after the ball array mask 19 was fixed, the ball cups 23a and 23b in the empty state of the solder balls 21 are sequentially moved over a plurality of (or four in the embodiment) height detection points preset outside of the insert section forming area 36, and the height of the upper face of the ball array mask 19 is measured. Incidentally, the measurements are not limited to the four detection points but may be continuously performed during the movement of the mask height detection sensor 27, as accompanying the movement of the ball cups 23a and 23b.

On the other hand, the height of the upper face of the ball array mask 19 in the insert section forming area 36 is determined by calculations. Moreover, the heights at the individual positions are calculated by considering the weights, which are applied to the ball cups 23a and 23b when the solder balls 21 are contained. At the ball mounting time, the ball cups 23a and 23b are moved in the X-axis direction and in the Y-axis direction such that their vertical movements are so controlled by the lifting means 45 that the clearance between the upper face of the ball array mask 19 and the lower faces of the ball cups 23a and 23b may not exceed a predetermined distance.

The wafer transfer stage 12, which carries the wafer 14 thereon, and is so mounted on the transfer passage 13 as to move in the X-axis direction. As shown in FIG. 3, the wafer transfer stage 12 has a Y-axis drive mechanism 28 acting as moving means of a direction (or a Y-axis direction) perpendicular to the transfer direction of the wafer 14, a θ-axis drive mechanism 29 or rotating means, and a Z-axis drive mechanism 30 or vertical moving means.

The actions of the solder ball mounting apparatus 1 of the embodiment are described in the following with reference to the accompanying drawings. First of all, the wafer 14 mounting the solder balls 21 is housed in the cassette 32 of the wafer supply section 6. Thus, one wafer 14 is extracted from the cassette 32 of the wafer supply section 6 and carried in the primary alignment section 7 by the carry-in robot 8. In the primary alignment section 7, the wafer 14 is rotated to detect the position of the orientation flat or notch thereby to correct the position of the wafer 14 roughly and to set the orientation flat or not at a predetermined position. Subsequently, the wafer 14 is carried by the carry-in robot 8 from the primary alignment section 7 to the wafer transfer stage 12 standby at the wafer transfer station 2.

The wafer transfer stage 12 carrying the wafer 14 is moved along the transfer passage 13 to the flux printing section 3 and stops at a predetermined position. Here, the alignment marks of the wafer 14 and the printing mask 15 are individually observed by the vertical observation cameras 31 so that the wafer transfer stage 12 is positioned in the X-axis direction by the X-axis drive mechanism 40 of the transfer passage 13, in the Y-axis direction by the Y-axis drive mechanism 28 and in the θ-axis direction by the θ-axis drive mechanism 29. After positioned, the wafer transfer state 12 is raised by the Z-axis drive mechanism 30 and stops at a predetermined height position with respect to the printing mask 15 prepared with the flux. In this state, the flux is fed to one end portion of the printing mask 15 in the Y-axis direction, and the squeegee is moved from one end portion to the other of the Y-axis direction so that the flux is printed from the through holes of the printing mask 15 onto the electrodes of the wafer 14.

After the flux printing action, the wafer transfer stage 12 is moved downward by the Z-axis drive mechanism 30, is moved to the ball mounting section 4 by the transfer passage 13 and stops at a predetermined position. At this position, the alignment marks of the wafer 14 and the ball array mask 19 are individually observed by the vertical observation camera 34 so that the wafer transfer stage 12 is positioned in the X-axis direction by the X-axis drive mechanism 40 of the transfer passage 13 and in the Y-axis direction and in the θ-axis direction by the Y-axis drive mechanism 28 and the θ-axis drive mechanism 29. After this, the wafer transfer stage 12 is raised by the Z-axis drive mechanism 30 and is stopped with leaving such a clearance between itself and the ball array mask 19 that the flux printed on the wafer 14 does not stick to the ball array mask 19.

Till then, the solder ball supply device 20 has positioned the ball cups 23a and 23b outside of the insert section forming area 36 of the ball array mask 19 and has housed the solder balls 21 in a predetermined amount in the ball cups 23a and 23b. When the wafer 14 is set below the ball array mask 19, the ball cups 23a and 23b are moved zigzag in the Y-axis direction over the ball array mask 19, and the solder balls 21 are dropped into the insert section 18 of the ball array mask 19 so that they are carried on the wafer 14. The ball cups 23a and 23b then perform the reciprocating motions, in which they move a predetermined stroke in the X-axis direction and then return in the Y-axis direction. The movement of the predetermined stroke in the X-axis direction is performed by an overrun of a distance from the position in the X-axis direction of the next ones of the solder balls 21 to be dropped into the ball cups 23a and 23b by one quarter or half of the cup width of the ball cup 23a, and by returning the ball cups 23a and 23b to the portion of the ball array mask 19 to drop the solder balls 21. In this meanwhile, the solder balls 21 are so supplied from the ball hopper 22 to the ball cups 23a and 23b that their quantity may be kept within a predetermined optimum range.

The supply of the solder balls 21 to the ball cups 23a and 23b is performed by the ball hopper 22. However, the ball array mask 19 is arranged while leaving such a clearance that the flux balls printed on the wafer 14 may not stick to the ball array mask 19. Therefore, it often occurs that the solder balls 21 do not fall if they are excessive in the ball cups 23a and 23b. In addition, the ball array mask 19 warps so much that the flux dangerously sticks or that the solder balls 21 become hard to fall for various causes. Thus, the solder balls 21 are diligently supplied to the minimum necessary number.

The solder balls 21 in the insert section 18 are positionally corrected after dropped, by moving the ball array mask 19 finely in the horizontal direction (i.e., in the X-axis direction and in the Y-axis direction) with respect to the wafer transfer state 12.

After having mounted the solder balls, the wafer transfer stage 12 is lowered, is moved to the delivery wafer transfer section 6 and is stopped by the Z-axis drive mechanism 30. In the wafer housing section 10, the wafer 14 is transferred from the wafer transfer stage 12 to the inverting unit 9 by the carry-out robot 11 and is turned so that the orientation flat or notch may come to the predetermined position. Moreover, the wafer 14 is transferred by the carry-out robot 11 from the inverting unit 9 to the cassette 32 of the wafer housing section 10. When the carry-out robot 11 extracts the wafer 14 from the wafer transfer stage 12, the wafer transfer stage 12 returns to the wafer transfer section 2 and ends one process. The present apparatus repeats the actions thus far described.

In the embodiment shown in FIG. 1, the wafer supply section 6 is disposed in front of the solder ball mounting apparatus 1, and the wafer housing section 10 is disposed at the back. The wafer transfer stage 12 returns to the original position. Therefore, as shown in FIG. 2, the wafer supply section 6 and the wafer housing section 10 may be disposed in the common direction, as shown in FIG. 2

According thereto, the carry-out robot 11 can be substituted for by the carry-in robot 8, and the wafer 4 is held and housed in the same direction as that of the wafer 14 being carried in, so that the inverting unit 9 can be omitted. In addition, one of the wafer transfer units 2 and 5 can be omitted to reduce the number of components.

Moreover, the means for positioning the printing mask 15, the ball array mask 19 and the wafer 14 is exemplified by the vertical observation cameras 31 and 34 for photographing the alignment mark of the wafer 14 and the printing mask 15 or the ball array mask 19 when the wafer transfer stage stops. However, the invention should not be limited thereto, but various structures can be conceived.

In this embodiment, the solder balls 21 are directly mounted on the electrodes on the upper face of the wafer 14, and the insert section 18 becomes the ball inserting section. In the invention, the solder balls 21 are once arrayed on the arraying jig having the ball housing recesses and are sucked from the arraying jig by the solder ball sucking head so that the solder balls 21 can be transferred to the object such as the electrodes on the wafer 14. In this case, the ball housing recesses are the ball inserting section.

What is claimed is:

1. A conductive ball arraying apparatus comprising:
an arraying jig having a conductive ball insert section;
a ball cup having an opening in a lower face thereof and being capable of housing a plurality of conductive balls together with the arraying jig; and
moving means which moves the ball cup zigzag along an upper face of the arraying jig and arrays the conductive balls.

2. The conductive ball arraying apparatus according to claim 1,
wherein the moving means moves the ball cup housing the conductive balls zigzag along the upper face of the arraying jig, falls the conductive balls from the opening of the ball cup into an insert section of the arraying jig and arrays the conductive balls.

3. The conductive ball arraying apparatus according to claim 1,
wherein the opening of the ball cup is narrower than a width of the area, and
wherein, when a proceeding direction of the ball cup is turned, the moving means moves perpendicularly to the proceeding direction.

4. The conductive ball arraying apparatus according to claim 1,
wherein a zigzag width of a direction to intersect a proceeding direction of the ball cup is one half or less of an array pitch in the same direction as that of an insert section of the arraying jig.

5. The conductive ball arraying apparatus according to claim 1,
wherein a quantity of the conductive balls to be housed in the ball cup is kept within a predetermined range.
